(19) United States
(12) Patent Application Publication
(10) Pub. No.: US 2025/0062722 A1
(43) Pub. Date: Feb. 20, 2025

(54) FREQUENCY-BASED COMPENSATION FOR POWER CONTROLLERS AND CONVERTERS

(71) Applicant: TEXAS INSTRUMENTS INCORPORATED, DALLAS, TX (US)

(72) Inventors: Ahmed Essam HASHIM, GILBERT, AZ (US); Jose VIDAL, PHOENIX, AZ (US)

(21) Appl. No.: 18/452,027

(22) Filed: Aug. 18, 2023

(51) Int. Cl. H03B 5/12; H03F 3/45

(52) U.S. Cl. CPC H03B 5/1253; H03B 5/1209; H03F 3/45183; H03F 2200/261

(57) ABSTRACT

A circuit includes an error amplifier including a reference input, a feedback input, and an error output. A compensation network has a frequency input and a compensation output, in which the compensation output is coupled to the error output. The compensation network configured to provide a variable capacitance between the compensation output and a ground terminal based on a frequency signal at the frequency input having a value representative of a frequency of a clock signal.

### TECHNICAL FIELD

This description relates to electrical circuits, in particular, to frequency-based compensation that can be used for power converters and power controllers.

### BACKGROUND

Power converter circuits, such as DC-DC converter and controller circuits, are used in numerous devices to supply power. In some example circuits, to reduce cost and enhance features, devices are configured to have low pin counts and implement internal fixed compensation. Fixed internal compensation typically is configured to operate over a limited expected range of switching frequencies. Consequently, converters and controls that implement such internal fixed compensation may exhibit poor performance in certain applications, particularly those that would adjust the switching frequency outside of the expected frequency range.

### SUMMARY

An example circuit an error amplifier including a reference input, a feedback input, and an error output. A compensation network has a frequency input and a compensation output, in which the compensation output is coupled to the error output. The compensation network configured to provide a variable capacitance between the compensation output and a ground terminal based on a frequency signal at the frequency input having a value representative of a frequency of a clock signal.

Another example circuit includes an error amplifier configured to provide an error signal at an error output based on a reference signal and feedback signal. An oscillator circuit is configured to provide a clock signal and a frequency signal having a value representative of a frequency of the clock signal. A compensation network has a variable capacitance and is configured to provide compensation at the error amplifier output based on the frequency signal.

As another example, a system includes an error amplifier including a reference input, a feedback input, and an error output. A compensation network has a frequency input and a compensation output, in which the compensation output is coupled to the error output, the compensation network configured to provide a variable capacitance between the compensation output and a ground terminal based on a frequency signal at the frequency input having a value representative of a frequency of a clock signal. An oscillator circuit includes a clock output and frequency output, in which the frequency output is coupled to the frequency input. A calibration circuit has a clock input, a compensation input, and first and second current outputs, in which the clock input is coupled to the clock output, the compensation input is coupled to the compensation output, and the first and second current outputs are coupled to respective inputs of the error amplifier

### BRIEF DESCRIPTION OF THE DRAWINGS

FIG. 1 is a block diagram of an example loop compensation circuit.

FIG. 2 is a circuit diagram of an example loop compensation circuit.

FIG. 3 is a circuit diagram of an example oscillator circuit.

FIG. 4 is a schematic diagram of an example calibration circuit.

FIG. 5 is a signal diagram showing example signals for the circuits of FIGS. 1 and 2.

FIG. 6 is a schematic diagram of an example power converter circuit implementing a loop compensation circuit.

### DETAILED DESCRIPTION

This description relates to electrical circuits, in particular, to frequency-based compensation that can be used for power converters and power controllers.

As an example, a circuit includes an error amplifier, a compensation network, and an oscillator circuit. The error amplifier includes a reference input, a feedback input, and a compensation output. The error amplifier is configured to provide an error signal at the compensation output based on a reference signal at the reference input and a feedback signal at the feedback input. The compensation network has a frequency input and a compensation output, in which the compensation output is coupled to the error output. The oscillator circuit has a clock output and a frequency output, in which the frequency output is coupled to the frequency input of the compensation network. The oscillator circuit is configured to provide a clock signal at the clock output and a frequency signal at the frequency output having a value representative of a frequency of the clock signal. The compensation network is configured to provide a variable capacitance, such as between the compensation output and a ground terminal of the circuit. The variable capacitance of the compensation network depends on a frequency of a clock signal. For example, the compensation network is configured to set the variable capacitance based on the frequency signal at the frequency input.

In some examples, the circuit includes a calibration circuit having a clock input, a compensation input, and first and second current outputs. The clock input can be coupled to the clock output, the compensation input can be coupled to the compensation output, and the first and second current outputs can be coupled to respective inputs of the error amplifier. The calibration circuit is configured to provide current to one or more of the first and second current outputs for calibrating the compensation network based on current at the compensation output.

The circuits and systems described herein provide an active calibrated compensation network that can adapt to the switching frequency. As a result, the circuits and system can provide useful compensation over a broad range of switching frequencies. Additionally, the circuits and system can be implemented in an integrated circuit (IC) or system on chip (SOC) at a lower cost, with less pins, and smaller area compared to many existing solutions. Also, the circuits and systems described herein can be implemented a power converters or power controllers. A power converter refers to a circuit (e.g., IC and SOC) that includes one or more power switches, such as transistors, which are driven by control electronics to provide output power at a desired level. A power controller refers to a circuit (e.g., IC and SOC) that is adapted to be coupled to one or more external power switches, such as transistors.

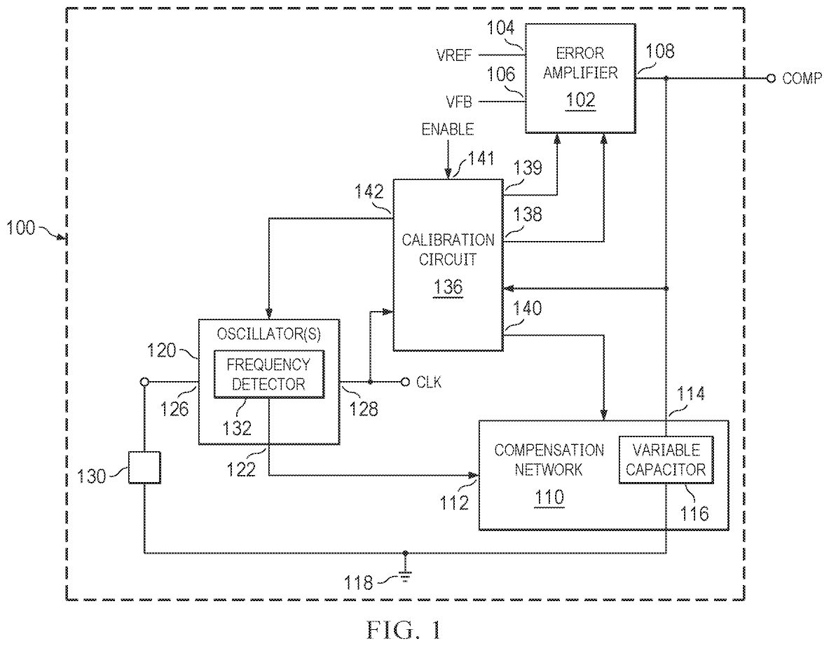

FIG. 1 is a block diagram of an example loop compensation circuit 100. The circuit includes an error amplifier 102 having a reference input 104, a feedback input 106, and an output 108. The error amplifier 102 is configured to provide an error signal at the output 108 based on a difference between a reference signal (e.g., a reference voltage VREF) at the input 104 and a feedback signal (e.g., a feedback voltage VFB) at the input 106. For example where the loop compensation circuit 100 is used to control a DC-DC power converter, the feedback voltage VFB is representative of an output voltage of a converter circuit that is controlled by the loop compensation circuit 100, and the reference voltage VREF represents a DC voltage to which power converter circuit is being regulated.

The circuit 100 also includes a compensation network 110 having a frequency input 112 and a compensation output 114. The compensation output 114 is coupled to the error output 108 (e.g., outputs 108 and 114 form the same node/terminal). The compensation network 110 includes a variable capacitance 116 between the compensation output 114 and a ground terminal 118. The variable capacitance 116 provides a capacitance based on a frequency signal at the frequency input 112 having a value representative of a frequency of a clock signal CLK. The loop compensation circuit 100 thus provides a compensation signal COMP based on the error signal at 108 and the capacitance (along with any other impedance) between the output 114 and the ground terminal 118.

An oscillator circuit 120 includes a frequency output 122 coupled to the frequency input 112 of the compensation network 110. The oscillator circuit 120 further includes a clock output 124 and a frequency control input 126. The oscillator circuit 120 is configured to provide the clock signal CLK at the clock output 128 and to provide the frequency signal at the frequency output 122. For example, a resistor and/or other passive component, shown at 130, can be coupled at the frequency control input 126 to provide a signal to set the switching frequency of the clock signal CLK (e.g., a 50% duty cycle square wave). The resistor can be a resistor external to an IC or SOC implementing the loop compensation circuit 100. The oscillator circuit 120 can also include a frequency detector 132 configured to provide the frequency signal at the frequency output 122 representative of the switching frequency of the clock signal. For example, the frequency detector 132 is configured to provide the frequency signal based on a signal at the frequency control input. In an example, the frequency detector 132 includes a voltage-to-current converter configured to provide the frequency signal at 122 as a current signal representative of (e.g., proportional to) the frequency of the clock signal CLK based on a voltage at the frequency control input 126. The oscillator circuit 120 or other circuitry can be configured to provide the frequency signal at 122 using a different approach in other examples.

Further still, the circuit 100 can include a calibration circuit 136 having a clock input and a compensation input, in which the clock input is coupled to the clock output 128 and the compensation input is coupled to the compensation output 108, 114. The calibration circuit 136 also include one or more current outputs 138 and one or more control outputs 139 coupled to one or more respective inputs of the error amplifier 102. The calibration circuit 136 is configured to calibrate the loop compensation circuit 100 during a calibration mode, such as at power up, responsive to an enable signal at a calibration enable input 141 thereof. The calibration circuit 136 can include logic configured to control providing different amounts of offset current (e.g., based on respective calibration current code values), at different times during the calibration mode, to the current output 138. The calibration circuit 136 can further be configured to monitor the compensation signal COMP at 114 for each calibration current code to detect a transition (e.g., a voltage or current transition) at the compensation output 114. The calibration circuit 136 is further configured to set (e.g., lock in) the respective current (e.g., by storing the respective calibration current code value) responsive to detecting the transition, which results in calibrating the loop compensation circuit 100, including by cancelling offsets in the error amplifier and the compensation network. Advantageously, the calibration can adaptively calibrate the offset for other sources of errors in the circuit 100.

The calibration circuit 136 can also include one or more control outputs 140 coupled to one or more respective control inputs of the compensation network, and one or more second control outputs 142 coupled to one or more respective control inputs of the oscillator circuit 120. The calibration circuit 136 is configured to provide calibration control signals at the respective control outputs 140 and 142 to configure the oscillator circuit 120 and compensation network 110 during the calibration mode to facilitate calibrating aggregate offset of the amplifier 102 and compensation network 110. For example, the oscillator circuit is configured during the calibration node, responsive to the calibration control signal at 142, to run at a known fixed frequency, to enable settling time in the error amplifier. The known fixed frequency can be independent of the frequency being set based on the frequency control signal at 126. As a further example, the compensation network 110 is configured, responsive to the calibration control signal at 140, to bypass the variable capacitor 116 to enable calibration independent of the switching frequency. By setting the fixed frequency and/or bypassing the capacitor during calibration, the settling times of the error amplifier circuit can be improved during calibration. After the calibration mode is complete, the calibration circuit 136 is configured to return the oscillator circuit 120 and the compensation network 110 to normal operating modes, in which the oscillator circuit 120 is configured to provide the clock signal with a switching frequency based on the frequency control signal at 120 and the variable capacitor is coupled between the compensation output 114 and the ground terminal 118.

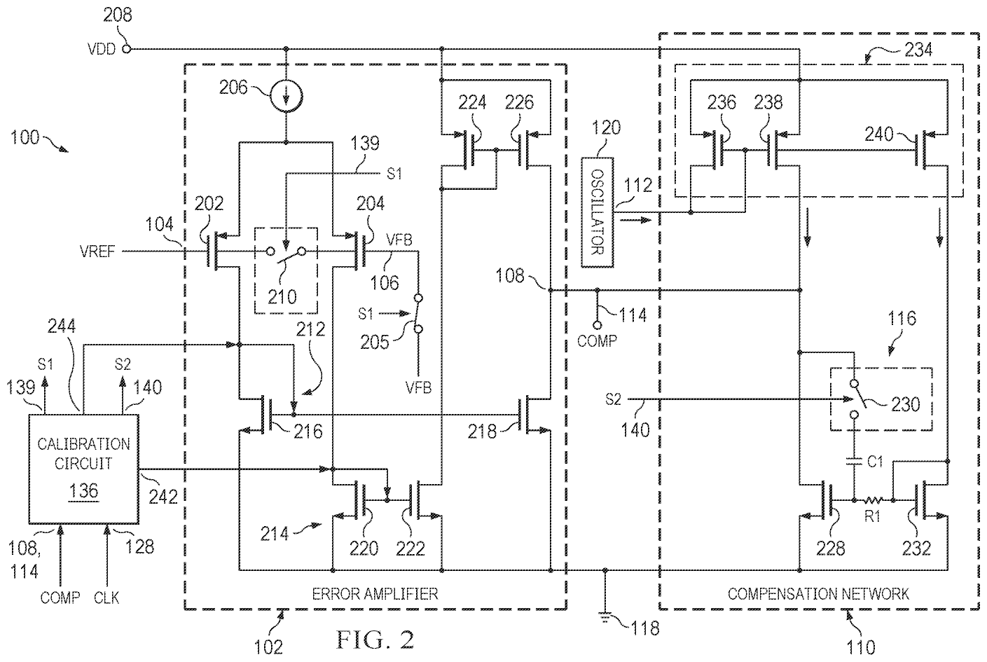

FIG. 2 is a circuit diagram of an example loop compensation circuit 200. The loop compensation circuit 200 in FIG. 2 provides a useful example of the loop compensation circuit 100 of FIG. 1. Accordingly, the description of FIG. 2 also refers to FIG. 1. The circuit 200 thus includes an error amplifier 102, a compensation network 110, an oscillator circuit 120 and a calibration circuit 136. The error amplifier 102 is configured to provide an error signal at the output 108 based on a difference between VREF and VFB.

In the example of FIG. 2, the error amplifier 102 includes transistors 202 and 204, in which the transistor 202 has a control input (e.g., gate) coupled to input 104 and the transistor 204 has a control input (e.g., gate) coupled to input 106 through a switch 205. Each transistor 202 and 204 also has a respective first current input (e.g., source) coupled together, and a current source 206 is coupled between a voltage terminal 208 (at a voltage VDD) and the first current inputs of the transistors 202 and 204. A switch 210 is coupled between the control inputs of the transistors 202 and 204. The transistor 202 has a second current input (e.g., drain) coupled to a first current mirror network 212, and the transistor 204 has a second current input (e.g., drain) coupled to a second current mirror network 214.

The first current mirror 212 includes a transistor 216 having a control input (e.g., gate), a first current input (e.g., source) and a second current input (e.g., drain), in which the first current input is coupled to the ground terminal 118. The second current input and the control input and drain of the transistor 216 are coupled to the second current input of the transistor 202 and to each other to form a diode-connected transistor. The control input of the transistor 216 is also coupled to a control input (e.g., gate) of another transistor 218. The transistor 218 includes a first current input (e.g., source) coupled to the ground terminal 118 and a second current input coupled to the output 108 of the error amplifier, which also constitutes the COMP output 114.

The second current mirror 214 includes a transistor 220 having a control input (e.g., gate), a first current input (e.g., source) and a second current input (e.g., drain), in which the first current input is coupled to the ground terminal 118. The second current input and the control input and drain of the transistor 220 are coupled to the second current input of the transistor 204 and to each other to form a diode-connected transistor. The control input of the transistor 220 is also coupled to a control input (e.g., gate) of another transistor 222. The transistor 222 includes a first current input (e.g., source) coupled to the ground terminal 118 and a second current input (e.g., drain) coupled to another current mirror, which includes transistors 224 and 226. The transistor 224 includes a control input (e.g., gate) coupled to the second current input of the transistor 222 and to a control input (e.g., gate) of the transistor 226. Each of the transistors 224 and 226 also has a first current input (e.g., source) coupled to the terminal 208. The transistor 226 also has a second current input (e.g., drain) coupled to and to the output 108 of the error amplifier 102, to which the second current input of the transistor 218 is also coupled.

The compensation network 110 includes a variable capacitor circuit 116. In the example of FIG. 2, the variable capacitor circuit 116 is implemented as a capacitive multiplier circuit (e.g., a transistor capacitive multiplier) coupled between the compensation output 114 and the ground terminal 118. For example, the capacitive multiplier circuit includes a transistor 228 having a first current input (e.g., source) coupled to the ground terminal 118 and a second current terminal (e.g., drain) coupled to the compensation output 114. A capacitor C1 is coupled between a control input (e.g., gate) of the transistor 228 and the compensation output 114. In some examples, a switch 230 is coupled between a terminal of the capacitor C1 and the compensation output 114 to selectively bypass the capacitor, as described herein. The control input of the transistor 228 is also coupled a control input (e.g., gate) of another transistor 232 through a resistor R1. The transistor 232 also has a first current input (e.g., source) and a second current input (e.g., drain), in which the first current input is coupled to the ground terminal 118. The second current input of the transistor 232 is coupled to the control input thereof. Other type and configurations of capacitive multiplier circuits (e.g., operational amplifier based capacitive multiplier) can be used in other examples.

The compensation network 110 also includes a current mirror network 234 coupled between the frequency input 112 and the capacitive multiplier circuit 116. For example, the current mirror network 234 includes transistors 236, 238 and 240. The transistor 236 has a control input (e.g., gate), a first current input (e.g., source) and a second current input (e.g., drain), in which the first current input is coupled to the voltage terminal 208. The second current input and the control input of the transistor 236 are each coupled to the frequency input 112 (and to each other). As described herein, the oscillator 120 is configured to provide a frequency input signal (e.g., a current signal) at 120 representative of a frequency of a clock signal. The control input of the transistor 236 is also coupled to a control input (e.g., gate) of transistors 238 and 240. The transistor 238 includes a first current input (e.g., source) coupled to the voltage terminal 208 and a second current input (e.g., drain) coupled to the compensation output 114. The transistor 240 includes a first current input (e.g., source) coupled to the voltage terminal 208 and a second current input (e.g., drain) coupled to the second current input of the transistor 232.

The calibration circuit 136 has current outputs 242 and 244 coupled to respective inputs of the error amplifier 102. In the example of FIG. 2, the current output 242 is coupled to the control input (and second current input) of the transistor 220, which constitutes an input to the current mirror 214. The other current output 244 is coupled to the control input and second current input of the transistor 216, which constitutes an input to the current mirror 212. The calibration circuit 136 is configured to provide offset current to one or more of the first and second current outputs 242 and 244 for calibrating the compensation network 110 based on current at the compensation output 114. For example, the current mirror networks 212 and 214 are configured to apply (e.g., source or sink) offset current at the output 108 of the error amplifier 102 based on the calibration current at 242 and 244.

As described herein, the calibration circuit 136 includes logic configured to adjust the offset current(s) at 242 and 244 during a calibration mode for calibrating the compensation network 110 to provide adaptive compensation at 114 according to the switching frequency of the clock signal CLK. The calibration circuit 136 thus includes a first control output 139 coupled to a control input of the switch 210 and the switch 205, and a second current output 140 coupled to the control input of the switch 230. In other examples, the calibration circuit can include different control outputs to control respective switches 205 and 210 during the calibration mode. During the calibration mode, the switch 210 is closed and the switch 205 is open in response to a control signal S1. The switch 230 is open in response to a control signal S2. The switch 210 couples the control inputs of transistors 202 and 204 to remove offset (e.g., to simulate a condition where VFB=VREF) and so the input stage provides balanced current to respective current mirrors 212 and 214, and any offset at the error amplifier output is removed by calibration. Also because control inputs of transistors 202 and 204 are coupled together through the closed switch 210, the switch 205 is opened so VREF and VFB are not shorted. The switch 230 is opened to remove the capacitance from the capacitance multiplier to enable offsets to be determined to reduce settling time at the error amplifier output. After calibration is complete and during normal operating mode, the switch 210 is open and the switch 230 is closed.

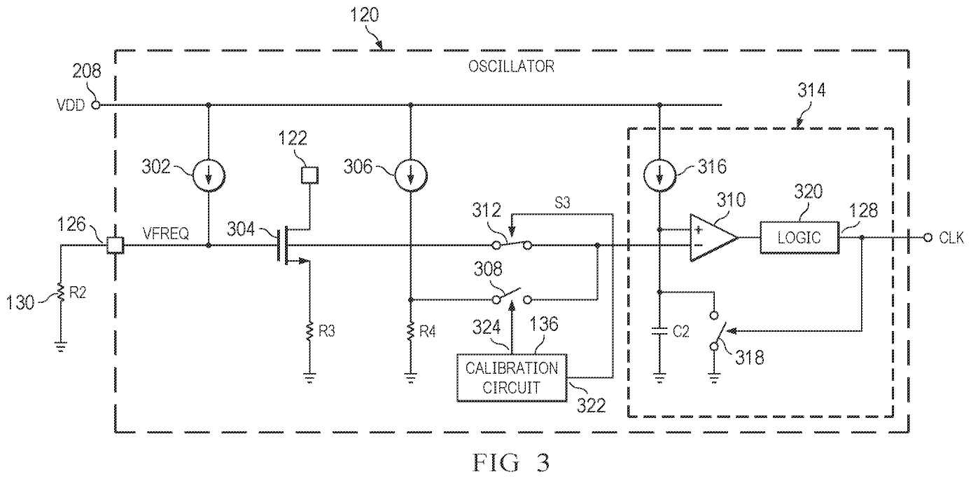

FIG. 3 is a circuit diagram of an example oscillator circuit 120 that can be used in the loop compensation circuit 100 of FIGS. 1 and 2. Accordingly, the description of FIG. 3 also refers to FIGS. 1 and 2. As described herein, the oscillator circuit 120 is configured to provide the clock signal CLK at clock output 128 based on a voltage at the frequency control input 126. For example, a resistor R2 and/or other passive component (e.g., external to the IC or SOC implementing the loop compensation circuit 100) is coupled at the frequency control input 126 to provide a voltage for setting the switching frequency of the clock signal CLK. In other examples, the frequency setting signal at 126 can be provided by other circuitry, internally or externally with respect to the IC or SOC.

In the example of FIG. 3, the oscillator circuit 120 includes a current source 302 coupled between voltage terminal 208 and the frequency control input 126. For example, the current source provides current through the resistor to provide an input voltage signal (VFREQ) at 126 for setting the switching frequency. A transistor 304 has a control input (e.g., gate) coupled to the frequency control input 126 and a source coupled to a ground terminal 118 through a resistor R3. A second current input of the transistor 304 is coupled to a frequency output 122, which is coupled to the frequency input 112 of the compensation network 110 (see, e.g., FIGS. 1 and 2). The transistor 304 and resistor thus form a voltage-to current converter configured to provide a current at 122 based on the input voltage signal (VFREQ) at 126, which is representative of the switching frequency of the clock signal. The current provided at 122 is based on the input voltage signal VFREQ independent of whether the circuit is in the calibration mode or normal operating mode.

The oscillator circuit 120 also include calibration clock circuit that includes a current source 306 coupled in series with a resistor R4 between the voltage terminal 208 and the ground terminal 118. A switch 308 is coupled between an intermediate node of the calibration clock circuit (e.g., between R4 and current source 306) and a first input (e.g., an inverting input) of a comparator 310. Another switch 312 is coupled between the frequency control input 126 and the first input of the comparator 310. Each of the switches 308 and 312 has a control input coupled to a respective control output of the calibration circuit 136.

The circuit 120 includes an oscillator network 314. In the example of FIG. 3, the oscillator includes the comparator 310, a current source 316, a capacitor C2, a switch 318 and logic 320. The capacitor C2 is coupled between a second input (e.g., a non-inverting input) of the comparator 310 and the ground terminal 118. The current source is coupled between the second input of the comparator 310 and the voltage terminal 208. The switch 318 is coupled between the second input of the comparator 310 and the ground terminal 118. The switch 318 also has a control input coupled to the clock output 128. Other designs and configurations of oscillators can be used in other examples.

The comparator 310 is configured to compare the voltages at the first and second inputs of the comparator 310 and provide a comparator output to the logic 320, which provides a logic output signal (e.g., a 50% duty cycle square wave) at 128 based on the comparison. The voltage at the first input is one of the voltage at 126 or the voltage across R4 depending on the state of the switches 308 and 312, which is based on the operating mode. The voltage at the second input is a time-varying signal (e.g., a ramp signal) based on the current sourced from the current source charging capacitor C2. When the voltage at the second input reaches the voltage at the first input, the comparator 310 provides an output to the logic, which in turn closes the switch 318 to reset the voltage at the second input of the comparator 310. The voltage signal provided at the first input of the comparator 310 thus determines the switching frequency of the clock signal CLK provided at 128.

The calibration circuit 136 is configured to control the switches 308 and 312 based on the operating mode, which further determines the switching frequency of the clock signal CLK. For example, during the calibration mode, the calibration circuit 136 provides switch control signals S3 and S4 at outputs 322 and 324, respectively, to open the switch 312 and close the switch 308. As a result, the calibration clock circuit is configured to provide a first voltage at the first input of the comparator 310 and configure the oscillator circuit 120 to provide fixed clock at a known frequency during the calibration mode. After the calibration mode is complete and during the normal operating mode, the calibration circuit 136 provides switch control signals S3 and S4 to close the switch 312 and open the switch 308. As a result, a second voltage is provided at the first input of the comparator 310 to configure the oscillator circuit 120 to provide the clock signal CLK with a switching frequency responsive to the frequency input signal VFREQ at 126, which is based on the resistance R2. As described herein, however, the oscillator circuit 120 is configured to provide the current signal at 122 to the compensation network, which is representative of the selected switching frequency based on VFREQ, independent of the operating mode, including when the clock signal CLK is set differently (e.g., to a known frequency) during the calibration mode. In some examples, the switching frequency of the clock signal CLK during calibration is lower than the switching frequency of the clock signal during normal operation, which is set based on the VFREQ signal at 126.

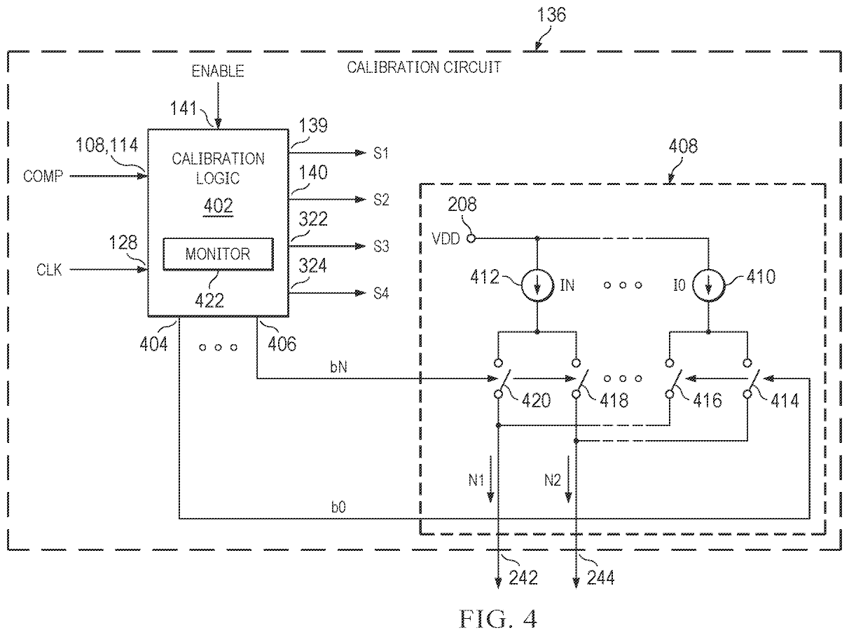

FIG. 4 is a schematic diagram of an example of the calibration circuit 136, which can be used in the circuits described with respect to FIGS. 1-3. Accordingly, the description of FIG. 4 also refers to FIGS. 1-3. The calibration circuit 136 includes calibration logic 402 having a compensation input coupled to output 1114, a clock input coupled to clock output 128 and a calibration enable input 141. The calibration logic 402 includes control outputs 139, 140, 322, and 324, as described herein, and two or more calibration current control outputs 404 and 406. There can be any number of two or more calibration current control outputs 404 and 406 as represented by an ellipsis between such outputs. The calibration current control outputs 404 and 406 can specify a code (e.g., a multi-bit binary code) to set an offset current provided at current outputs 242 and/or 244. The calibration logic 402 can be implemented by a controller (e.g., a dedicated or multi-function controller), an arrangement of logic gates, a field programmable gate array, or other circuitry configured to calibrate offset currents for the compensation network 110, such as described herein.

The calibration circuit 136 also includes a calibration current network 408 having inputs coupled to the respective current control outputs 404 and 406 and current outputs 242 and 244 coupled to respective inputs of the error amplifier 102 (see, e.g., FIG. 2). In the example of FIG. 4, the calibration current network 408 includes a number (e.g., N+1) of current sources 410 and 412, where N is a positive integer. Each of the current sources 410 and 412 is coupled between the voltage terminal 208 and a respective pair of switches 414, 416 and 418, 420. For example, one of the switches 414 and 418 of each switch pair is coupled to the current output 244 and the other of the switches 416 and 420 of each switch pair is coupled to the other current output 242. Also, each switch of the pair of switches 414 and 416 has a control input coupled one of the current control outputs 404 and each switch in other pair of switches has a control input coupled to a different one of the current control outputs 406.

As an example, when enabled responsive to the enable signal at 139, the calibration logic 402 operates in the calibration mode in which the logic is configured to activate a different one of the switches at a given time (e.g., during one or more switching cycles) so that one (or more) of the current sources 410 and 412 is coupled to a respective one (or more) of the current outputs to inject offset current into the error amplifier 110. As described with respect to FIG. 2, the offset current provided at 242 and/or 244 can be injected into respective current mirrors 214 and/or 212. The calibration logic also includes a compensation monitor 422, which is coupled to the compensation output 108, 114. The compensation monitor 422 can be configured to detect a state change in the signal at the compensation output 108, 114, which indicates that the amount of offset current being injected results in a desired compensation for the selected switching frequency of the clock signal. For example, the compensation monitor 422 is configured to monitor a voltage at the compensation output 108, 114 and detect a state change from a high to low voltage or from a low to high voltage. The type of transition (e.g., a high-to-low or low-to-high transition) that indicates a desired level of compensation has been achieved can vary depending on how the calibration logic cycles through the offset current. In response to the state change being detected (e.g. by monitor 422), the calibration logic 402 can provide signals at respective outputs 139, 140, 322 and 324 having values to indicate the calibration mode is complete. After the calibration mode is complete, the calibration code (e.g., a multi-bit binary value) at outputs 404 and 406 is locked in, such as by storing the calibration code in memory (e.g., a register) of the calibration logic 402, to provide a corresponding offset current at one or more of the current outputs 242 and 244. Also, after the calibration mode is complete, the various parts of the circuit can operate in a normal operating mode. Each time the circuit powers up, the calibration circuit 136 can re-calibrate the offset currents to provide desired compensation, as described herein.

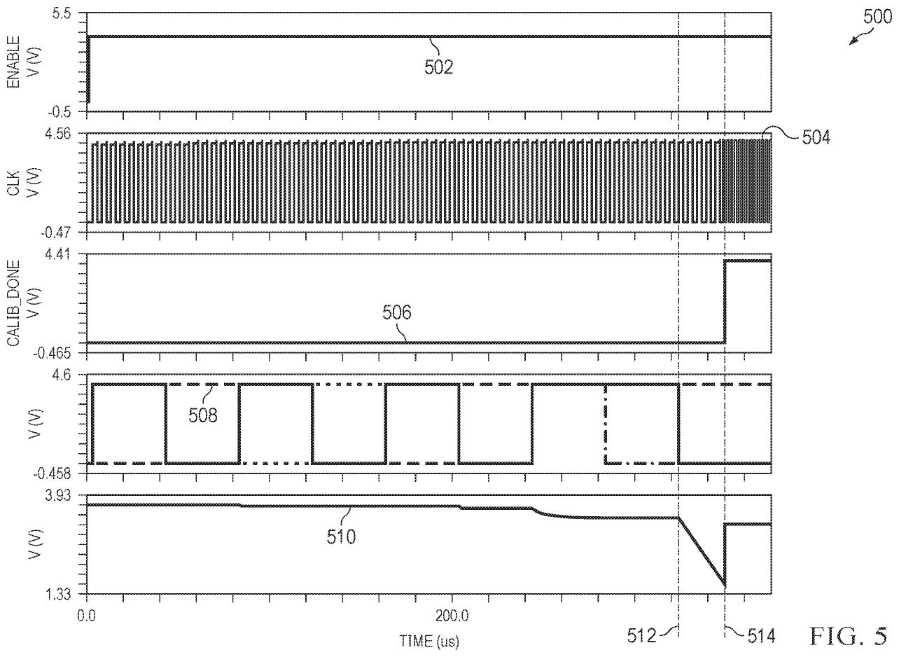

FIG. 5 is a signal diagram 500 showing example signal waveforms 502, 504, 506 and 508 for the circuits of FIGS. 1-4 as part of a process of calibrating the compensation network 110, such as described herein. The signal 502 shows an enable signal (e.g., at 141) representing the circuit is active, such as at power up. The signal 502 shows the clock signal CLK over time. The signal 504 represents a calibration done logic signal. The signals at 506 represent control bits (e.g., corresponding to different calibration codes) that are provided by the calibration logic 402 to respective switches 414, 416, 418 and 420 of the calibration current network 408 to control offset current provided at 242 and 244 during the calibration mode. The signal 508 represents a voltage at the compensation output 108, 114 during the calibration mode, in which the voltage has an initial high-voltage offset based on the calibration circuit injecting current to the error amplifier 102. At 510 the voltage at the compensation output 108, 114 transitions from a high-voltage to a low-voltage, which is representative of no offset current at the compensation output and calibration being complete. The calibration circuit 136 can be configured to provide a calibration done condition in response to detecting the transition condition at 108, 114 and to lock-in (e.g., store in memory) the calibration code that triggered the transition condition. At 510, the calibration mode has ended and normal operation of the compensation circuit 100 begins, including changing of the switching frequency of the clock signal from the fixed frequency signal to the desired switching frequency responsive to the signal at the frequency control input 126.

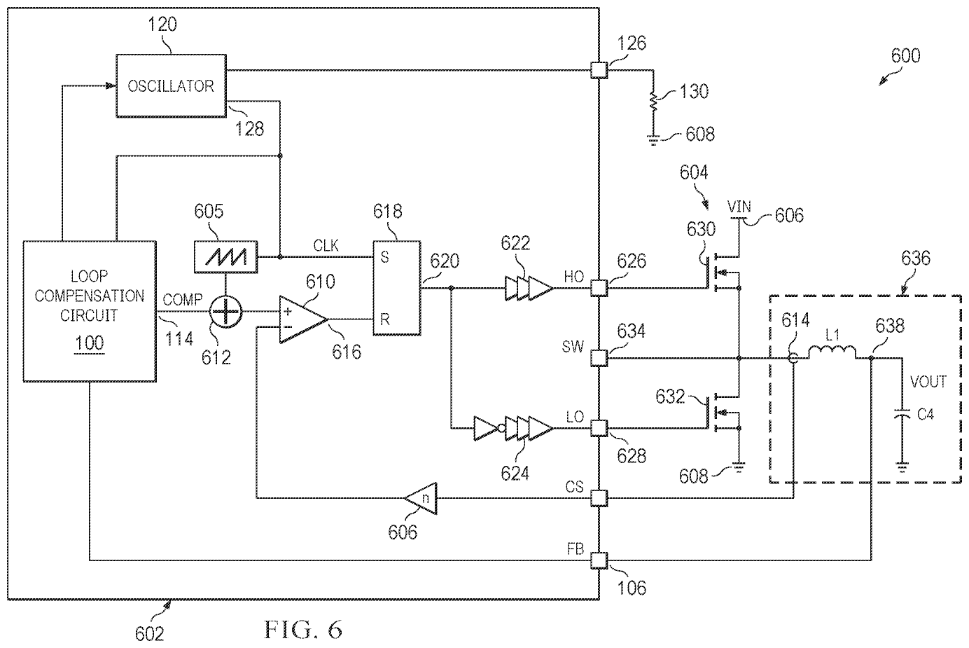

FIG. 6 is a schematic diagram of an example power converter circuit 600 that includes a loop compensation circuit 100, such as described herein (see, e.g., FIGS. 1-4). Accordingly, the description of FIG. 6 also refers to FIGS. 1-5. The circuit 600 includes a loop control circuit 602, shown as an IC or SOC. The loop control circuit 602 includes an arrangement of circuitry configured to control an output power stage 604 coupled between an input voltage terminal 606 and a ground terminal 608 (e.g., ground terminal 118). The output power stage 604 can be external to the IC or SOC, such as shown in the example of FIG. 6, or the power stage can be implemented within the IC or SOC to provide an integrated power converter.

The loop control circuit 602 includes an oscillator 120, which is shown external to the loop compensation circuit 100. In other examples the oscillator 120 can be part of the loop compensation circuit 100. The oscillator 120 has a frequency control input 126 and a clock output 128. A resistor 130 (or other device) can be coupled between the input and a ground terminal to set a frequency of the clock signal CLK generated by the oscillator 120.

The loop control circuit 602 includes a comparator 610 which has one input coupled to an output of a current sense amplifier 606 and another input coupled to an output of a summer circuit 612. In an example, the summer circuit 612 is coupled to an output of a sawtooth generator 614 and a compensation output 114 of a loop compensation circuit 100. The sawtooth generator is configured to provide a sawtooth signal (or another oscillating signal waveform, such as a triangle or sinusoidal waveform) at a switching frequency responsive to the clock signal CLK at 128. The loop compensation circuit 100 is configured to provide a compensation signal at 114 as described herein (see, e.g., FIGS. 1-5). The summer circuit 612 is configured to provide a compensated sawtooth signal based on the COMP signal and the sawtooth signal. The current sense amplifier 606 as an input coupled to a current sense input CS of the circuit 602, which is coupled to a current sensor 614 configure to sense output current provided by the power converter circuit 600. The current sense amplifier 606 thus is configured to provide an amplified signal representative of the sensed current. The comparator 610 is configured to provide a comparator output signal at an output 616 based on the compensated sawtooth signal at and the current sense signal. For example, the comparator output signal at 616 includes a series of pulses.

A logic circuit 618 has a first input coupled to the comparator output 616 and a second input coupled to the clock output 128. The logic circuit 618 also has a logic output 620 coupled to inputs of high-side and low side drivers 622 and 624. The high-side and low side drivers 622 and 624 have respective outputs coupled to high-side and low-side drive outputs 626 and 628 of the loop control circuit 602. In the example of FIG. 6, the output stage includes transistors (e.g., field effect transistors) 630 and 632 configured as a half-bridge between the voltages terminal 606 and the ground terminal 608. The transistor 630 has a control input (e.g., gate), a first current input (e.g., source), a second current input (e.g., drain), in which the control input is coupled to the output 626, the first current input is coupled to a switching terminal 634 of the circuit 602, and the second current input is coupled to the voltage terminal 606. The transistor 632 has a control input (e.g., gate), a first current input (e.g., source), a second current input (e.g., drain), in which the control input is coupled to the output 628, the first current input is coupled to the ground terminal 608, and the second current input is coupled to the switching terminal 634.

For example, the logic circuit 618 is a digital circuit configured to provide the logic control signal as a series of pulses (e.g., logic 0 or 1) having a variable pulse width, such as a pulse-width modulated (PWM) logic signal, based on the comparator output signal at 616 and the clock signal CLK at 128. The high-side and low side drivers 622 and 624 are configured to amplify the logic control signal at 620 to provide respective drive signals at outputs 626 and 628 sufficient to drive transistors (e.g., power field effect transistors) 626 and 628. For example, the gate drive signals are inverted versions of each other to turn on and off transistors 626 and 628 in a mutually exclusive manner. The transistors 626 and 628 thus provide current and voltage at the switching terminal 634 based on the drive signals at 626 and 628. An output circuit 636, shown as including inductor L1 and a capacitor C4, can be coupled to the switching terminal 634 to provide an output voltage VOUT at a power converter output 638 based on a switching voltage at the switching terminal.

The loop compensation circuit 100 thus enables the loop control circuit 602 to implement internal compensation for the power converter circuit (e.g., DC-DC converter) 600 that is self-adjusting based on the switching frequency, which can vary for a given application. As a result, the overall transient performance of the power converter circuit 600 can be improved over many existing designs, particularly those that implement an adjustable switching frequency. Additionally, the approach described herein can be implemented as a lower cost solution due by using less pins and a smaller on-chip area to implement the loop compensation circuit 100.

In this description, the term “based on” means based at least in part on.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, a device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof. Furthermore, a circuit or device described herein as including certain components may instead be configured to couple to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be configured to couple to at least some of the passive elements and/or the sources to form the described structure, either at a time of manufacture or after a time of manufacture, such as by an end user and/or a third party.

Modifications are possible in the described embodiments, and other embodiments are possible, within the scope of the claims.

What is claimed is:

1. A circuit, comprising:
an error amplifier including a reference input, a feedback input, and an error output; and
a compensation network having a frequency input and a compensation output, in which the compensation output is coupled to the error output, the compensation network configured to provide a variable capacitance between the compensation output and a ground terminal based on a frequency signal at the frequency input having a value representative of a frequency of a clock signal.

2. The circuit of claim 1, further comprising an oscillator circuit including a frequency output coupled to the frequency input.

3. The circuit of claim 2, wherein the oscillator circuit further includes a clock output and a frequency control input, in which the oscillator circuit is configured to provide the clock signal at the clock output and to provide the frequency signal at the frequency output.

4. The circuit of claim 3, wherein the oscillator circuit comprises a frequency detector configured to provide the frequency signal at the frequency output based on a signal at the frequency control input, and the oscillator circuit is configured to provide the clock signal at the clock output based on the signal at the frequency control input.

5. The circuit of claim 4, wherein the frequency detector comprises a voltage-to-current converter configured to provide the frequency signal as a current signal representative of the frequency of the clock signal based on a voltage at the frequency control input.

6. The circuit of claim 3, further comprising a calibration circuit having a clock input, a compensation input, and first and second current outputs, in which the clock input is coupled to the clock output, the compensation input is coupled to the compensation output, the first current output is coupled to a first offset input of the error amplifier, and the second current output is coupled to a second offset input of the error amplifier.

7. The circuit of claim 6, wherein, during a calibration mode, the calibration circuit is configured to provide current to at least one of the first and second current outputs and calibrate the compensation network based on a transition current at the compensation output.

8. The circuit of claim 6, further comprising:
a first switch coupled between the reference input and the feedback input, the first switch having a first control input; and
a second switch coupled between the variable capacitance and the compensation output, the second switch having a second control input, wherein the calibration circuit includes a first control output coupled to the first control input and a second control output coupled to the second control input.

9. The circuit of claim 8, wherein the calibration circuit is configured to provide calibration control signals at the first and second control outputs to close the first switch and open the second switch during a calibration mode and, responsive to completion of the calibration mode, to open the first switch and close the second switch when the calibration mode is complete.

10. The circuit of claim 6, wherein:
the oscillator circuit comprises a frequency detector circuit configured to provide the frequency signal at the frequency output based on a signal at the frequency control input, and
the oscillator circuit is configured to provide the clock signal at the clock output at a calibration frequency responsive to a calibration control signal indicating a calibration mode and with another frequency, which is based on the signal at the frequency control input, responsive to the calibration control signal indicating the calibration mode is complete.

11. The circuit of claim 10, wherein the calibration frequency is independent of the other frequency.

12. A circuit comprising:
an error amplifier configured to provide an error signal at an error amplifier output based on a reference signal and feedback signal;
an oscillator circuit is configured to provide a clock signal and a frequency signal having a value representative of a frequency of the clock signal; and
a compensation network having a variable capacitance is configured to provide compensation at the error amplifier output based on the frequency signal.

13. The circuit of claim 12, wherein the compensation network comprises a capacitance multiplier circuit having the variable capacitance based on the frequency signal.

14. The circuit of claim 12, further comprising a calibration circuit, which is configured during a calibration mode to provide current to the error amplifier and calibrate the compensation network based on the frequency signal.

15. The circuit of claim 12, wherein the oscillator circuit comprises a frequency detector circuit configured to provide the frequency signal responsive a frequency control input signal, and the oscillator circuit is configured to provide the clock signal based on the frequency control input signal.

16. The circuit of claim 15, wherein the frequency detector circuit comprises a voltage-to-current converter configured to provide the frequency signal as a current signal representative of the frequency of the clock signal based on a voltage of the frequency control input signal.

17. The circuit of claim 15, wherein the oscillator circuit is configured to provide the clock signal at a first frequency responsive to a calibration control signal indicating the circuit is in a calibration mode and at a second frequency, which is based on the frequency control input signal, responsive to the calibration control signal indicating the calibration mode is complete, and the first frequency is independent of the second frequency.

18. A system comprising:
an error amplifier including a reference input, a feedback input, and an error output;
a compensation network having a frequency input and a compensation output, in which the compensation output is coupled to the error output, the compensation network configured to provide a variable capacitance between the compensation output and a ground terminal based on a frequency signal at the frequency input having a value representative of a frequency of a clock signal;
an oscillator circuit including a clock output and frequency output, in which the frequency output is coupled to the frequency input; and
a calibration circuit having a clock input, a compensation input, and first and second current outputs, in which the clock input is coupled to the clock output, the compensation input is coupled to the compensation output, and the first and second current outputs are coupled to respective inputs of the error amplifier.

19. The system of claim 18, wherein:
the oscillator circuit is configured to provide the clock signal at the clock output and to provide the frequency signal at the frequency output,
the error amplifier is configured to provide an error signal at the error output based on a reference signal at the reference input and a feedback signal at the feedback input,
the compensation network is configured to provide a compensation signal at the error output based on the frequency signal, and
the calibration circuit is configured to provide current to at least one of the first and second current outputs and calibrate the compensation network based on current at the compensation output.

20. The system of claim 19, wherein:
the oscillator circuit is configured to provide the clock signal at a first frequency responsive to a calibration control signal indicating the system is in a calibration mode and at a second frequency, which is based on a frequency control input signal, responsive to the calibration control signal indicating the calibration mode is complete, and the first frequency is independent of the second frequency, and
the compensation network comprises a capacitance multiplier circuit having the variable capacitance based on the frequency signal.
